(19) United States
(12) Patent Application Publication
(10) Pub. No.: US 2015/0028187 A1
(43) Pub. Date: Jan. 29, 2015

(54) IMAGE SENSOR DEVICE WITH INFRARED FILTER ADHESIVELY SECURED TO IMAGE SENSOR INTEGRATED CIRCUIT AND RELATED METHODS

(71) Applicant: STMICROELECTRONICS PTE LTD, Singapore (SG)

(72) Inventors: Yonggang JIN, Singapore (SG); Bin-Hong HUANG, Singapore (SG)

(73) Assignee: STMICROELECTRONICS PTE LTD, Singapore (SG)

(21) Appl. No.: 13/948,507

(22) Filed: Jul. 23, 2013

(51) Int. Cl. H01L 31/18; H01L 27/146

(52) U.S. Cl. CPC H01L 31/1876; H01L 27/14625
USPC 250/208.1; 438/65

(57) ABSTRACT

An image sensor device may include a mounting substrate having an IC-receiving cavity therein and a filter-receiving opening aligned with the IC-receiving cavity, an image sensor integrated circuit (IC) within the IC-receiving cavity and having an image sensing area aligned with the filter-receiving opening, and an adhesive bead on the image sensor IC surrounding the image sensing area. Furthermore, an infrared (IR) filter may be within the filter-receiving opening and have peripheral portions contacting the adhesive bead.

### FIELD OF THE DISCLOSURE

The present disclosure relates to the field of electronic devices, and, more particularly, to image sensors and related methods.

### BACKGROUND

Typically, electronic devices include one or more camera modules for providing enhanced media functionality. For example, the typical electronic device may utilize the camera modules for photo capturing and video teleconferencing. In the typical electronic device with multiple camera modules, the primary camera module has a high pixel density and an adjustable focus lens system, while the secondary camera module is front-facing and has a lower pixel density. Also, the secondary camera module may have a fixed focus lens system.

For example, U.S. Patent Application No. 2009/0057544 to Brodie et al., which is assigned to the present application's assignee, discloses a camera module for a mobile device. The camera module comprises a lens, a housing carrying the lens, and a lens cap over the lens and housing. The camera module includes a barrel mechanism for adjusting the lens.

During manufacture of an electronic device including one or more camera modules, there is a desire to manufacture the electronic device as quickly as possible, particularly in mass production runs. The typical camera module is manufactured in a multi-step process. The first steps include semiconductor processing to provide the image sensor integrated circuit (IC). The next steps include some form of testing for the image sensor IC and packaging. The image sensor IC may be assembled into the camera module, along with a lens and movable barrel if needed. This assembly of the camera module may be performed manually or via machine. For example, in electronic devices that use surface mounted components, a pick-and-place (PNP) machine may assemble the components onto a printed circuit board (PCB). A drawback to such singular packaging is that it may be relatively inefficient and also may require that each device be tested individually, adding to the manufacturing time.

In some applications, it may helpful to manufacture the image sensor IC to include an infrared (IR) filter glass. In one approach, an IR filtering glass is attached over the image sensor IC, as will be discussed further below with reference to FIG. 6. Infrared (IR) cut-off filters are used with color CCD or CMOS imagers to produce accurate color images. An IR cut-off filter blocks the transmission of the infrared while passing the visible. This can be done with two optical techniques: absorption or reflection. Absorptive filters are made with special optical glass that absorbs near infrared radiation. Reflection type filters are short-pass interference filters that reflect infrared light with high efficiency. A potential drawback to this approach is that the overall thickness of the device may be increased, which may be undesirable for tight fitted mobile applications.

Referring to FIG. 6, one example approach to an image sensor device 200 is shown. The image sensor device 200 illustratively includes a ceramic substrate 201, a plurality of metal interconnects 202, and an image sensor IC 203 carried within a cavity 204 in the substrate. More particularly, the image sensor IC 203 is suspended from the upper surface of the cavity 204, and coupled to the metal interconnects 202 by solder beads 205. An image sensor array or area 206 is on an upper surface of the image sensor IC 203 and faces upward. An opening 207 in the ceramic substrate 201 corresponds with the sensor array area 206 to expose the sensor array area to light. Also, the image sensor device 200 further illustratively includes an IR filter 208 that is positioned over and above the opening 207, which is coupled to the upper surface of the substrate 201 by an adhesive layer 209. The IR filter 208 accordingly blocks IR radiation to prevent exposure to the sensor array area 206. A lens assembly (not shown) may be positioned over the IR filter 208 in some embodiments.

A potential drawback to such approaches is that the overall thickness of the device may be increased. However, this may be undesirable for mobile or other applications with relatively tight space tolerances, for example.

### SUMMARY

An image sensor device may include a mounting substrate having an IC-receiving cavity therein and a filter-receiving opening aligned with the IC-receiving cavity, an image sensor integrated circuit (IC) within the IC-receiving cavity and having an image sensing area aligned with the filter-receiving opening, and an adhesive bead on the image sensor IC surrounding the image sensing area. Furthermore, an infrared (IR) filter may be within the filter-receiving opening and have peripheral portions contacting the adhesive bead. As such, the image sensor device may advantageously have a relatively low profile, for example.

More particularly, the image sensor device may further include an adhesive layer securing the IR filter to adjacent portions of the mounting substrate within the filter-receiving opening. Furthermore, the adhesive layer may contact the adhesive bead. By way of example, the adhesive bead may be opaque.

The mounting substrate may have an upper surface, and the IR filter may have an upper surface aligned flush with the upper surface of the mounting substrate. Furthermore, the image sensor device may further include an optical lens assembly carried by the mounting substrate and aligned with the IR filter. By way of example, the IR filter may comprise an IR glass layer. Additionally, the image sensor device may further include a plurality of conductive interconnects carried by the mounting substrate and electrically coupled with the image sensor.

A related method is for making an image sensor device. The method may include forming a mounting substrate having an IC-receiving cavity therein and a filter-receiving opening aligned with the IC-receiving cavity, mounting an image sensor integrated circuit (IC) within the IC-receiving cavity and having an image sensing area aligned with the filter-receiving opening, forming an adhesive bead on the image sensor IC surrounding the image sensing area, and securing an IR filter within the filter-receiving opening and with peripheral portions contacting the adhesive bead.

### BRIEF DESCRIPTION OF THE DRAWINGS

FIG. 1 is a cross-sectional view of an image sensor device including a flush-mount IR filter in accordance with an example embodiment.

FIGS. 2-5 are a series of cross-sectional views illustrating a method of making the image sensor device of FIG. 1.

FIG. 6 is a cross-sectional view of a prior art image sensor device.

### DETAILED DESCRIPTION OF THE EMBODIMENTS

The present disclosure will now be described more fully hereinafter with reference to the accompanying drawings, in which embodiments of the disclosure are shown. These embodiments may, however, be embodied in many different forms and should not be construed as limited to the embodiments set forth herein. Rather, these embodiments are provided so that this disclosure will be thorough and complete, and will fully convey the scope of the present disclosure to those skilled in the art. Like numbers refer to like elements throughout.

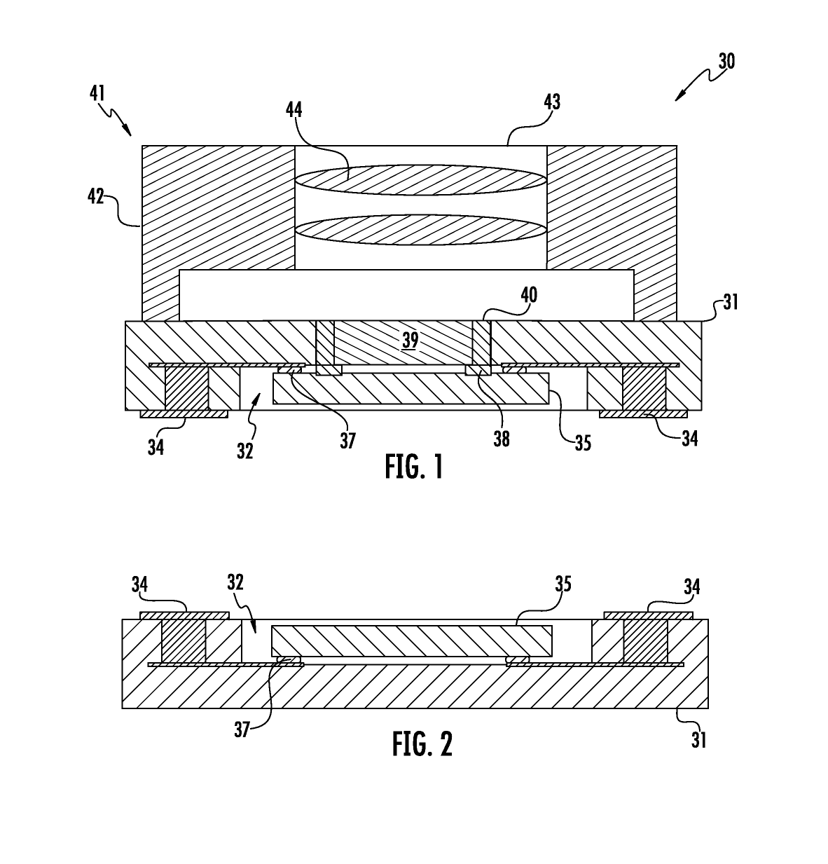

Referring initially to FIGS. 1-5, an example embodiment of an image sensor device 30 and associated method for making the same are first described. The image sensor device 30 illustratively includes a mounting substrate 31 having an integrated circuit (IC) receiving cavity 32 therein, and a filter-receiving opening 33 (FIG. 3) aligned with the IC-receiving cavity. By way of example, the mounting substrate 31 may be a ceramic substrate formed using low-temperature co-fired ceramic (LTCC) techniques, for example, although other suitable substrate materials may also be used in different embodiments. Electrically conductive (e.g., metal) interconnects 34 are also carried by the mounting substrate 31, which may be incorporated into the substrate as part of the LTCC formation process, as will be appreciated by those skilled in the art, for example.

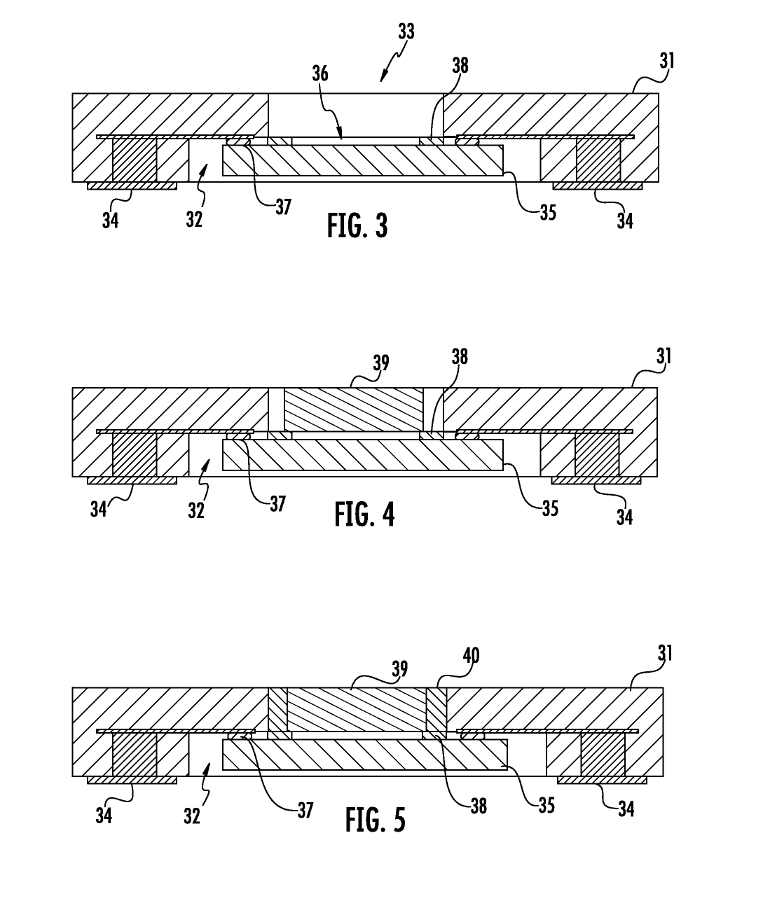

An image sensor IC 35 may be mounted within the IC-receiving cavity 32 which has an image sensing area 36 aligned with the filter-receiving opening 33. By way of example, the image sensor IC 35 may include a semiconductor substrate, such as a through silicon via (TSV) substrate, with a charge-coupled device (CCD) or CMOS image sensor, as will be appreciated by those skilled in the art. As seen in FIG. 2, the mounting substrate 31 may be turned upside down for mounting of the image sensor IC 35 within the IC-receiving cavity 32. More particularly, solder beads 37 may be used to physically and electrically couple the image sensor IC 35 to the conductive interconnects 34.

Following mounting of the image sensor IC 35, the substrate 31 may be turned over so that an adhesive bead 38 may be formed on the image sensor IC 35 surrounding the image sensing area 36 (FIG. 3). Furthermore, an infrared (IR) filter 39 may be secured within the filter-receiving opening 33 by placing peripheral portions of the IR filter in contact with the adhesive bead 38. More particularly, the adhesive bead 38 may be a generally annular bead that is positioned to hold the IR filter 39 within the filter-receiving opening 33, yet not run onto the image sensing area 36. However, other bead shapes may be used, and in some embodiments the adhesive bead 38 may be applied to the IR filter 39 prior to placement of the IR filter on the image sensor IC 35.

Furthermore, an adhesive layer 40 may be formed within the filter-receiving opening 33 between the IR filter 39 and the sidewall of the filter-receiving opening which contacts the adhesive bead 38 and helps secure the IR filter 39 in place. More particularly, the adhesive bead 38 and the adhesive layer 40 may be opaque (e.g., black, etc.) to prevent the passage of light therethrough and circumventing the IR filter 39. Moreover, the adhesive bead 38 and the adhesive layer 40 may be performed as a multi-step process with an intermediate curing phase for the adhesive bead before insertion of the adhesive for the adhesive layer. This may not only provide a firm foundation for the IR filter 39 to rest upon the image sensor IC 35, but the adhesive bead 38 also helps provide a barrier against any adhesive from the adhesive layer 40 seeping onto the image sensor area 36, for example.

In accordance with one example, using typical IC adhesives for the adhesive bead 38 and the adhesive layer 40, a curing time of about 15 minutes to 3 hours may be used at a temperature in a range of about 80° C. to 150° C., although other curing times and temperatures may be used in different embodiments. Furthermore, in some embodiments a relatively fast-setting adhesive may be used which does not require elevated temperatures and may set in a relatively short period of time, as will be appreciated by those skilled in the art. Additionally, in some embodiments the IR filter 39 may be sized to fit within the filter-receiving opening 33 such that the adhesive layer 40 is not required.

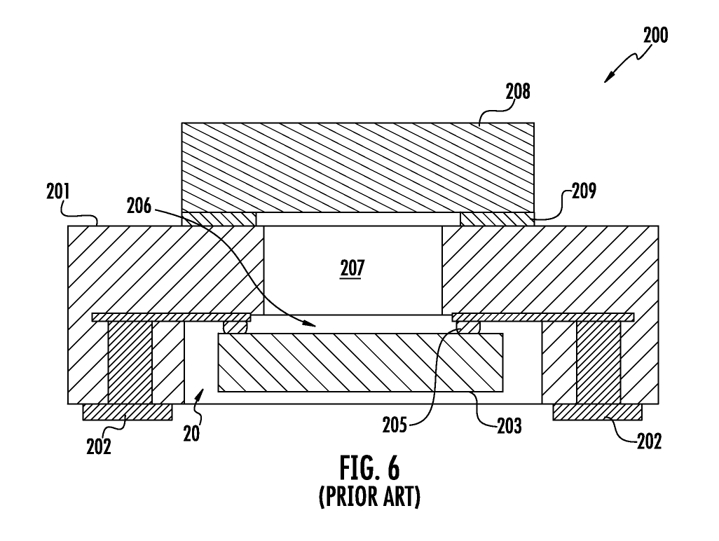

By way of example, the IR filter 39 may comprise a layer of IR glass, as described above, which may advantageously have its upper surface aligned flush with an upper surface of the mounting substrate 31. This helps lower the overall height profile of the image sensor device 30 relative to configurations such as that discussed above with reference to FIG. 6. In some embodiments, an optical lens assembly 41 may optionally be positioned on the mounting substrate 31 and aligned with the IR filter 39 to direct light onto the image sensing area 36, as will be appreciated by those skilled in the art. The optical lens assembly 41 illustratively includes a housing 42, a lens barrel 43 carried by the housing, and a plurality of lenses 44 carried by the lens barrel. The housing 42 may comprise a lens actuator (not shown) for adjusting the position of the lens barrel 43.

It will accordingly be appreciated that the image sensor device 30 may be used in numerous applications and electronic devices, such as in photo and video image capture applications, motion detection applications, etc. Moreover, the image sensor device 30 may be used in fixed focus lens as well as adjustable lens applications, for example.

Many modifications and other embodiments of the present disclosure will come to the mind of one skilled in the art having the benefit of the teachings presented in the foregoing descriptions and the associated drawings. Therefore, it is understood that the present disclosure is not to be limited to the specific embodiments disclosed, and that modifications and embodiments are intended to be included within the scope of the appended claims.

That which is claimed is:

1. An image sensor device comprising:
a mounting substrate having an IC-receiving cavity therein and a filter-receiving opening aligned with the IC-receiving cavity;
an image sensor integrated circuit (IC) within the IC-receiving cavity and having an image sensing area aligned with the filter-receiving opening; and
an adhesive bead on said image sensor IC surrounding the image sensing area;
an infrared (IR) filter within the filter-receiving opening and having peripheral portions contacting said adhesive bead.

2. The image sensor device of claim 1 further comprising an adhesive layer securing said IR filter to adjacent portions of said mounting substrate within the filter-receiving opening.

3. The image sensor device of claim 2 wherein said adhesive layer contacts said adhesive bead.

4. The image sensor device of claim 1 wherein said adhesive bead is opaque.

5. The image sensor device of claim 1 wherein said mounting substrate has an upper surface and said IR filter has an upper surface aligned flush with the upper surface of said mounting substrate.

6. The image sensor device of claim 1 further comprising an optical lens assembly carried by said mounting substrate and aligned with said IR filter.

7. The image sensor device of claim 1 wherein said IR filter comprises an IR glass layer.

8. The image sensor device of claim 1 further comprising a plurality of conductive interconnects carried by said mounting substrate and electrically coupled with said image sensor.

9. An image sensor device comprising:
a mounting substrate having an IC-receiving cavity therein and a filter-receiving opening aligned with the IC-receiving cavity;
an image sensor integrated circuit (IC) within the IC-receiving cavity and having an image sensing area aligned with the filter-receiving opening;
an infrared (IR) filter within the filter-receiving opening;
an adhesive bead on said image sensor IC surrounding the image sensing area;
an infrared (IR) filter within the filter-receiving opening and having peripheral portions contacting said adhesive bead; and
an adhesive layer securing said IR filter to adjacent portions of said mounting substrate within the filter-receiving opening;
said adhesive bead and said adhesive layer each being opaque.

10. The image sensor device of claim 9 wherein said mounting substrate has an upper surface and said IR filter has an upper surface aligned flush with the upper surface of said mounting substrate.

11. The image sensor device of claim 9 further comprising an optical lens assembly carried by said mounting substrate and aligned with said IR filter.

12. The image sensor device of claim 9 wherein said IR filter comprises an IR glass layer.

13. A method for making an image sensor device comprising:
forming a mounting substrate having an IC-receiving cavity therein and a filter-receiving opening aligned with the IC-receiving cavity;
mounting an image sensor integrated circuit (IC) within the IC-receiving cavity and having an image sensing area aligned with the filter-receiving opening;
forming an adhesive bead on said image sensor IC surrounding the image sensing area; and
securing an infrared (IR) filter within the filter-receiving opening and with peripheral portions contacting the adhesive bead.

14. The method of claim 13 comprising further securing the IR filter to adjacent portions of the mounting substrate within the filter-receiving opening with an adhesive layer.

15. The method of claim 14 wherein the adhesive layer contacts the adhesive bead.

16. The method of claim 13 wherein the adhesive bead is opaque.

17. The method of claim 13 further comprising aligning flush upper surfaces of the mounting substrate and IR filter.

18. The method of claim 13 further comprising mounting an optical lens assembly on the mounting substrate and aligned with the IR filter.

19. The method of claim 13 wherein the IR filter comprises an IR glass layer.

20. The method of claim 13 further comprising coupling the image sensor to a plurality of conductive interconnects carried by the mounting substrate.
